(19) United States
(12) Patent Application Publication
(10) Pub. No.: US 2009/0029296 A1
(43) Pub. Date: Jan. 29, 2009

(54) IMAGE RECORDING METHOD AND DEVICE

(75) Inventors: Issei Suzuki, Kanagawa-ken (JP); Katsuto Sumi, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Minato-ku, Tokyo (JP)

(21) Appl. No.: 11/910,204

(22) PCT Filed: Mar. 28, 2006
(86) PCT No.: PCT/JP2006/306362

§ 371 Date: Jan. 11, 2008

(30) Foreign Application Priority Data
Mar. 28, 2005 (JP) 2005-091645

(51) Int. Cl. G03F 7/22; G03B 27/42

(52) U.S. Cl. 430/322; 355/53

(57) ABSTRACT

A light quantity of a laser beam (L) outputted from exposure heads (24a-24j) is detected by a photosensor (68). At a light quantity locality data calculating section (88), light quantity locality correcting data for correcting the locality of the detected light quantity is calculated by divided area of a DMD (36) which constitutes exposure heads (24a-24j). Mask data for having a specified micromirror (40) of the DMD (36) in an off state fixedly is set by using the light quantity locality correcting data.

### TECHNICAL FIELD

The present invention relates to a method of and an apparatus for recording an image on an image recording medium by controlling a plurality of recording components arrayed along the image recording medium depending on image data.

### BACKGROUND ART

FIG. 14 is a view illustrative of a process of manufacturing a printed wiring board. A substrate 2 with a copper foil 1 deposited thereon by evaporation or the like is prepared. A photoresist 3 made of a photosensitive material is pressed with heat against (laminated on) the copper foil 1. After the photoresist 3 is exposed to light according to a wiring pattern by an exposure apparatus, the photoresist 3 is developed by a developing solution. Then, the portion of the photoresist 3 which has not been exposed is removed. The copper foil 1 that is exposed by the removal of the photoresist 3 is etched away by an etching solution. Thereafter, the remaining photoresist 3 is peeled off by a peeling solution. As a result, a printed wiring board having the copper foil 1 left in the desired wiring pattern on the substrate 2 is manufactured.

There has been developed a spatial light modulator such as a digital micromirror device (DMD) or the like, for example, as the exposure apparatus for recording the wiring pattern on the photoresist 3 (see U.S. Pat. No. 5,132,723). The DMD comprises a number of micromirrors tiltably disposed in a grid-like array on SRAMs (memory cells). The micromirrors have respective surfaces with a highly reflective material such as aluminum or the like being evaporated thereon. When a digital signal representative of image data is written into SRAM cells, the corresponding micromirrors are tilted in a given direction depending on the digital signal, selectively turning on and off light beams and directing the turned-on light beams to the photoresist 3 to record a wiring pattern by exposure.

The light beams reflected by the respective micromirrors and led to the photoresist 3 may have different intensities, beam diameters, beam shapes, etc., depending on the location. On the substrate 2 where the wiring pattern is to be formed, the laminated state of the photoresist 3 may differ depending on the location due to irregularities of heating temperature and pressure, and chemical reaction rates may become irregular in chemical processes such as the developing process and the etching process. For these reasons, it may not be possible to form wiring patterns of desired line widths on the substrate 2.

### DISCLOSURE OF THE INVENTION

It is a general object of the present invention to provide a method of and an apparatus for recording a desired image highly accurately on an image recording medium.

A major object of the present invention is to provide a method of and an apparatus for recording an image while eliminating image irregularities depending on the position on an image recording medium.

### BRIEF DESCRIPTION OF THE DRAWINGS

FIG. 1 is an external perspective view of an exposure apparatus according to an embodiment of the present invention;

FIG. 2 is a schematic view of an exposure head of the exposure apparatus according to the embodiment;

FIG. 3 is an enlarged fragmentary view showing a DMD employed in the exposure head shown in FIG. 2;

FIG. 4 is a view illustrative of an exposure recording process performed by the exposure head shown in FIG. 2;

FIG. 5 is a diagram showing the DMD of the exposure head shown in FIG. 2 and mask data set in the DMD;

FIG. 6 is a diagram showing the relationship between a recording position and an amount-of-light locality in the exposure apparatus according to the embodiment;

FIG. 7 is a diagram showing a line width recorded when the amount-of-light locality shown in FIG. 6 is not corrected;

FIG. 8 is a diagram showing a line width recorded when the amount-of-light locality shown in FIG. 6 is corrected;

FIG. 9 is a block diagram of a control circuit of the exposure apparatus according to the embodiment;

FIG. 10 is a flowchart of a process of generating mask data which is performed by the exposure apparatus according to the embodiment;

FIG. 11 is a diagram illustrative of divided areas of the DMD of the exposure apparatus according to the embodiment;

FIG. 12 is a diagram illustrative of amount-of-light locality data calculated with respect to the respective areas shown in FIG. 11;

FIG. 13 is a diagram showing the relationship between amounts of change in beam diameters for photosensitive materials of different types and amounts of change in line widths; and

FIG. 14 is a view illustrative of a process of manufacturing a printed wiring board.

### BEST MODE FOR CARRYING OUT THE INVENTION

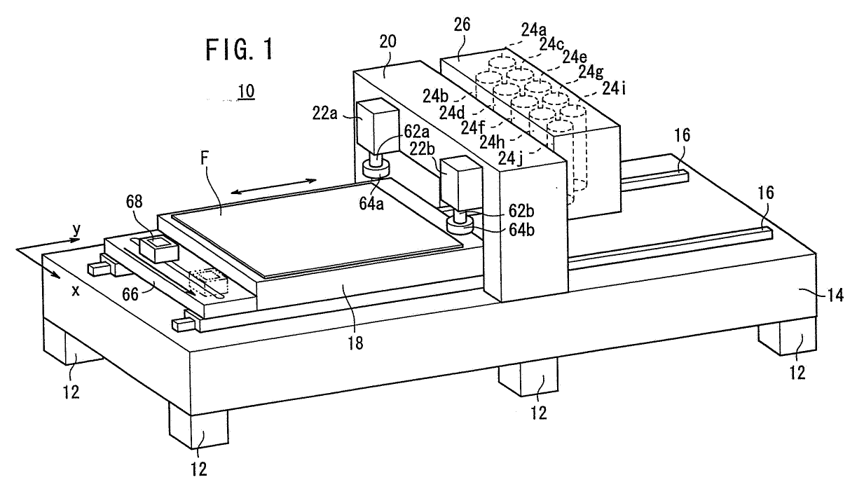

FIG. 1 shows an exposure apparatus 10 for performing an exposure process on a printed wiring board, etc., to which an image recording method and an image recording apparatus according to an embodiment of the present invention are applied. The exposure apparatus 10 has a bed 14, which suffers very little deformations, supported by a plurality of legs 12, and an exposure stage 18 mounted on the bed 14 by two guide rails 16 for reciprocating movement in the directions indicated by the arrow. An elongate rectangular substrate F (image recording medium) coated with a photosensitive material is attracted to and held on the exposure stage 18.

A portal column 20 is mounted centrally on the bed 14 over the guide rails 16. Two CCD cameras 22a, 22b are fixed to one side of the column 20 for detecting the position in which the substrate F is mounted with respect to the exposure stage 18. A scanner 26 having a plurality of exposure heads 24a through 24j positioned and held therein for recording an image on the substrate F by way of exposure is fixed to the other side of the column 20. The exposure heads 24a through 24j are arranged in two staggered rows in a direction perpendicular to the directions in which the substrate F is scanned (the directions in which the exposure stage 18 is movable). Flash lamps 64a, 64b are mounted on the CCD cameras 22a, 22b, respectively, by respective rod lenses 62a, 62b. The flash lamps 64a, 64b apply an infrared radiation to which the substrate F is insensitive, as illuminating light, to an image capturing area for the CCD cameras 22a, 22b.

A guide table 66 which extends in the direction perpendicular to the directions in which the exposure stage 18 is movable is mounted on an end of the bed 14. The guide table 66 supports thereon a photosensor 68 (locality measuring means) movable in the direction indicated by the arrow x for detecting the amount of light of laser beams L emitted from the exposure heads 24a through 24j.

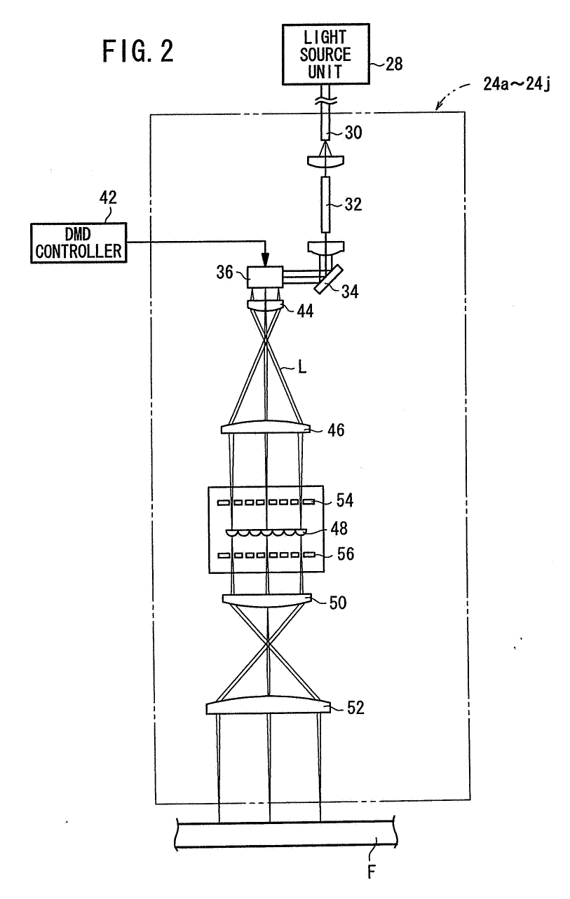

FIG. 2 shows a structure of each of the exposure heads 24a through 24j. A combined laser beam L emitted from a plurality of semiconductor lasers of light source units 28 is introduced through an optical fiber 30 into each of the exposure heads 24a through 24j. A rod lens 32, a reflecting mirror 34, and a digital micromirror device (DMD) 36 are successively arranged on an exit end of the optical fiber 30 into which the laser beam L is introduced.

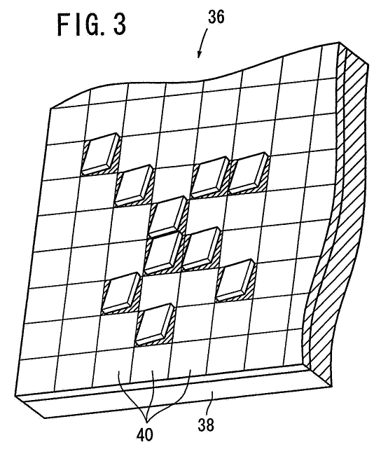

As shown in FIG. 3, the DMD 36 comprises a number of micromirrors 40 (recording components) that are swingably disposed in a matrix pattern on SRAM cells (memory cells) 38. A material having a high reflectance such as aluminum or the like is evaporated on the surface of each of the micromirrors 40. When a digital signal according to image recording data is written in the SRAM cells 38 by a DMD controller 42, the micromirrors 40 are tilted in given directions depending on the applied digital signal. Depending on how the micromirrors 40 are tilted, the laser beam L is turned on or off.

In the direction in which the laser beam L reflected by the DMD 36 that is controlled to be turned on or off is emitted, there are successively disposed first image focusing optical lenses 44, 46 of a magnifying optical system, a microlens array 48 having may lenses corresponding to the respective micromirrors 40 of the DMD 36, and second image focusing optical lenses 50, 52 of a zooming optical system. Microaperture arrays 54, 56 for removing stray light and adjusting the laser beam L to a predetermined diameter are disposed in front of and behind the microlens array 48.

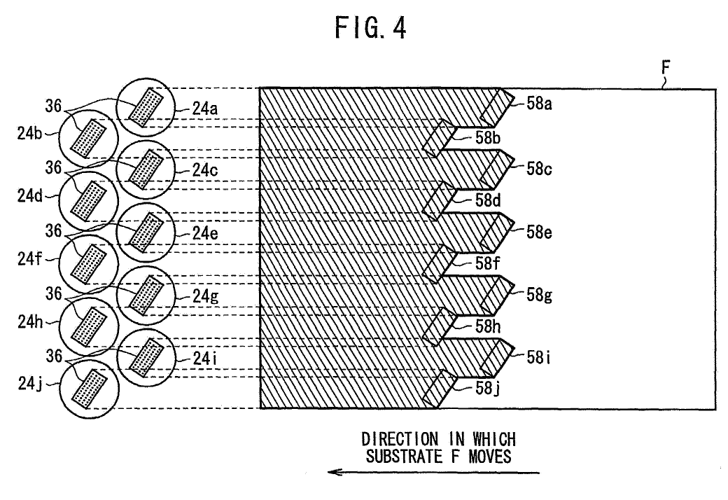

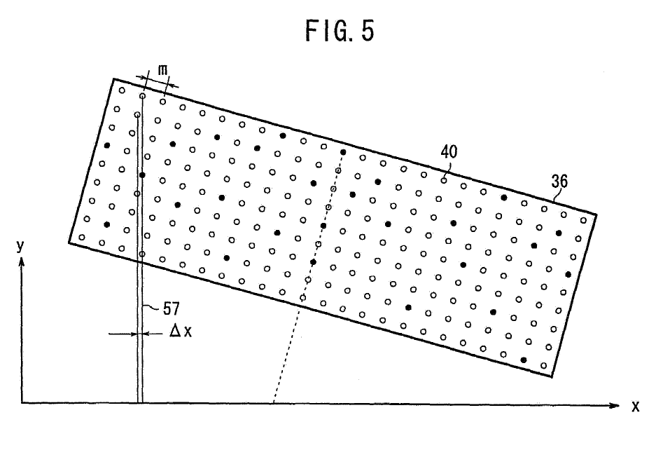

As shown in FIGS. 4 and 5, the DMDs 36 incorporated in the respective exposure heads 24a through 24j are inclined a predetermined angle to the direction in which the exposure heads 24a through 24j move, for achieving higher resolution. Specifically, the DMDs 36 that are inclined to the direction in which the substrate F is scanned (the direction indicated by the arrow y) reduce the interval Δx between the micromirrors 40 in the direction (the direction indicated by the arrow x) perpendicular to the direction in which the substrate F is scanned, to a value smaller than the interval m between the micromirrors 40 of the DMDs 36 in the direction in which they are arrayed, thereby increasing the resolution.

In FIG. 5, a plurality of micromirrors 40 are disposed on one scanning line 57 in the scanning direction (the direction indicated by the arrow y) of the DMDs 36. The substrate F is exposed to a multiplicity of images of one pixel by laser beams L that are guided to substantially the same position by these micromirrors 40. In this manner, amount-of-light irregularities between the micromirrors 40 can be averaged. To make the exposure heads 24a through 24j seamless, they are arranged such that exposure areas 58a through 58j which are exposed at a time by the respective exposure heads 24a through 24j overlap in the direction indicated by arrow x.

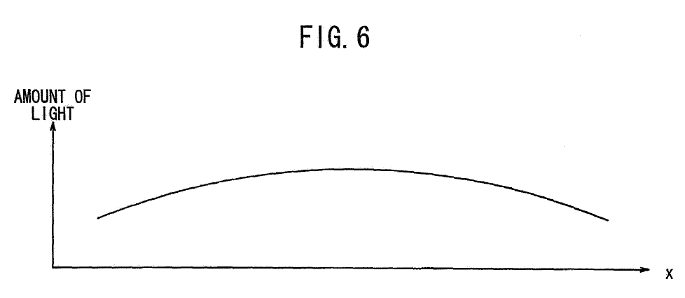

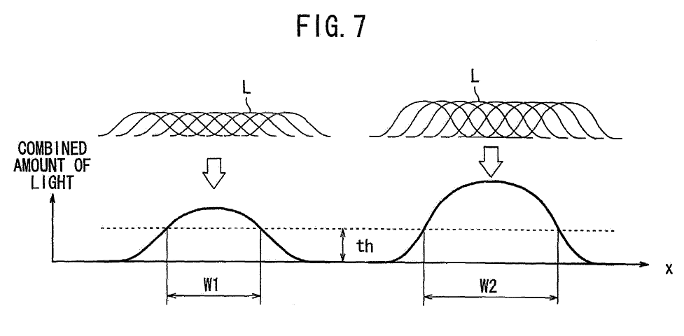

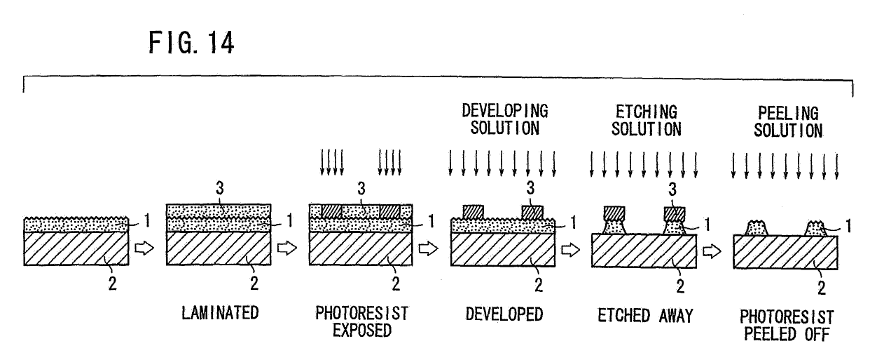

As shown in FIG. 6, the amount of light of the laser beam L that is guided to the substrate F by each of the micromirrors 40 of the DMDs 36 has a locality caused by the reflectance of the DMDs 36 along the direction indicated by the arrow x in which the exposure heads 24a through 24j are arrayed, and the recording characteristics of the optical systems. With such a locality, as shown in FIG. 7, when an image is recorded on the substrate F by laser beams L having a smaller combined amount of light which are reflected by a plurality of micromirrors 40 and when an image is recorded on the substrate F by laser beams L having a greater combined amount of light which are reflected by the micromirrors 40, the images have respective different widths W1, W2 in the direction indicated by the arrow x which are determined by a threshold th beyond which the photosensitive material applied to the substrate F is sensitive to the laser beams L. As shown in FIG. 14, when the exposed substrate F is processed by a developing process, an etching process, and a peeling process, the widths of the images are also varied by recording characteristics such as photoresist lamination irregularities, developing process irregularities, etching process irregularities, and peeling process irregularities as well as the locality of the amount of light of the laser beams L.

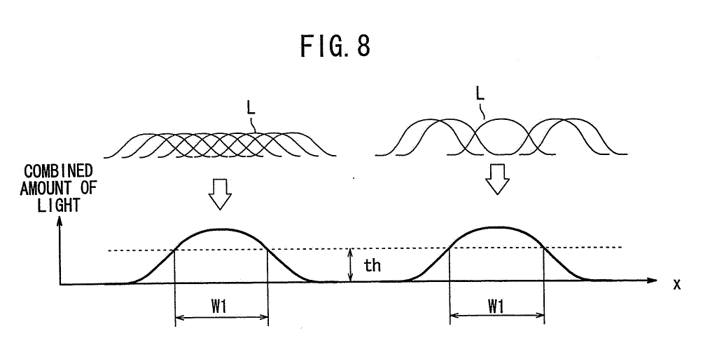

According to the present embodiment, in view of the locality of the amount of light of the laser beams L among the above various factors responsible for the variations, the number of micromirrors 40 that are used to form one pixel of image on the substrate F is set and controlled using mask data to produce images having a constant width W1 regardless of the positions in the direction indicated by the arrow x, as shown in FIG. 8.

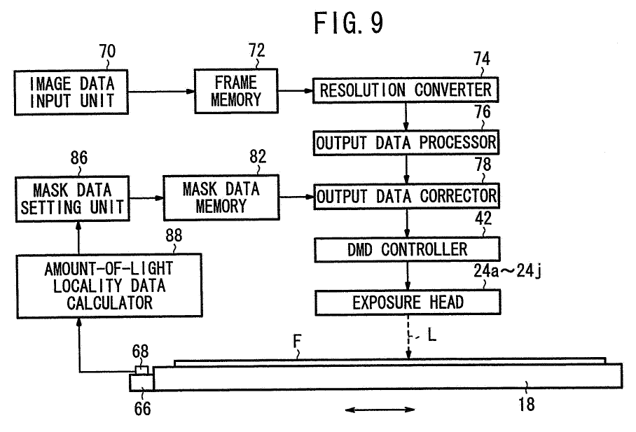

FIG. 9 shows in block form a control circuit of the exposure apparatus 10 having a function to perform such a control process.

The exposure apparatus 10 has an image data input unit 70 for entering image data to be recorded on the substrate F by exposure, a frame memory 72 for storing the entered two-dimensional image data, a resolution converter 74 for converting the resolution of the image data stored in the frame memory 72 into a higher resolution depending on the size and layout of the micromirrors 40 of the DMDs 36 of the exposure heads 24a through 24j, an output data processor 76 for processing the resolution-converted image data into output data to be assigned to the micromirrors 40, an output data corrector 78 for correcting the output data according to mask data, a DMD controller 42 (recording component control means) for controlling the DMDs 36 according to the corrected output data, and the exposure heads 24a through 24j for recording a desired image on the substrate F with the DMDs 36 that are controlled by the DMD controller 42.

A mask data memory 82 (mask data storage means) for storing mask data is connected to the output data corrector 78. The mask data are data for specifying micromirrors 40 to be turned off at all times. The mask data are set by a mask data setting unit 86. The exposure apparatus 10 also has an amount-of-light locality data calculator 88 for calculating amount-of-light locality data based on the amounts of light of the laser beams L detected by the photosensor 68. The amount-of-light locality data calculated by the amount-of-light locality data calculator 88 are supplied to the mask data setting unit 86 (mask data setting means).

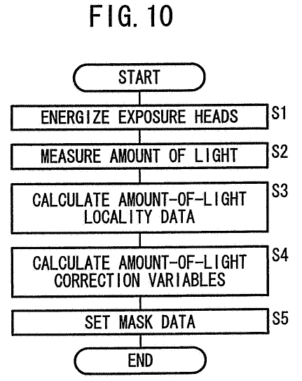

The exposure apparatus 10 according to the present embodiment is basically constructed as described above. A process of setting mask data will be described below with reference to a flowchart shown in FIG. 10.

First, the exposure stage 18 is moved to place the photosensor 68 beneath the exposure heads 24a through 24j. Thereafter, the exposure heads 24a through 24j are energized (step S1). At this time, the DMD controller 42 sets all the micromirrors 40 of the DMDs 36 to an on-state for reflecting the laser beams L.

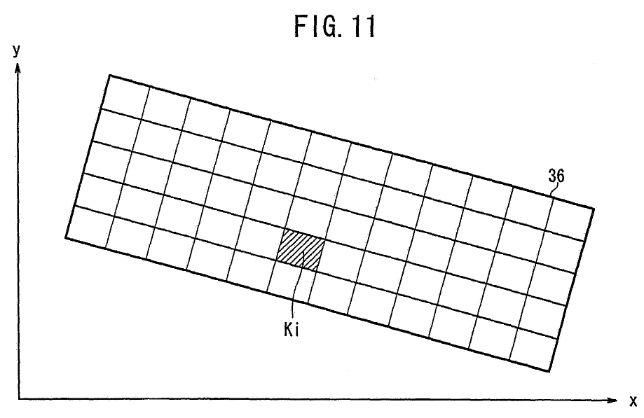

While moving the exposure stage 18 in the direction indicated by the arrow y in FIG. 1, the photosensor 68 is moved in the direction indicated by the arrow x and measures the amounts of light of the laser beams L emitted from the exposure heads 24a through 24j (step S2). As shown in FIG. 11, the DMD 36 is divided into areas Ki (i=1, 2, . . . ) each comprising a group of adjacent micromirrors 40. Amounts Pi (i=1, 2, . . . ) of light of the laser beams L obtained from the micromirrors 40 of the areas Ki (i=1, 2, . . . ) are measured by the photosensor 68.

The measured amounts Pi (i=1, 2, . . . ) of light from the areas Ki (i=1, 2, . . . ) are supplied to the amount-of-light locality data calculator 88 which calculates amount-of-light locality data Si (i=1, 2, . . . ) in the areas Ki (i=1, 2, . . . ) from the amount Pi (i=1, 2, . . . ) of light (step S3).

Specifically, the amount-of-light locality data calculator 88 calculates a maximum value Pmax of the amounts Pi (i=1, 2, . . . ) of light from the areas Ki (i=1, 2, . . . ), calculates amount-of-light locality data Si (i=1, 2, . . . ) that have been standardized based on the maximum value Pmax as follows:

Si=Pi/Pmax,

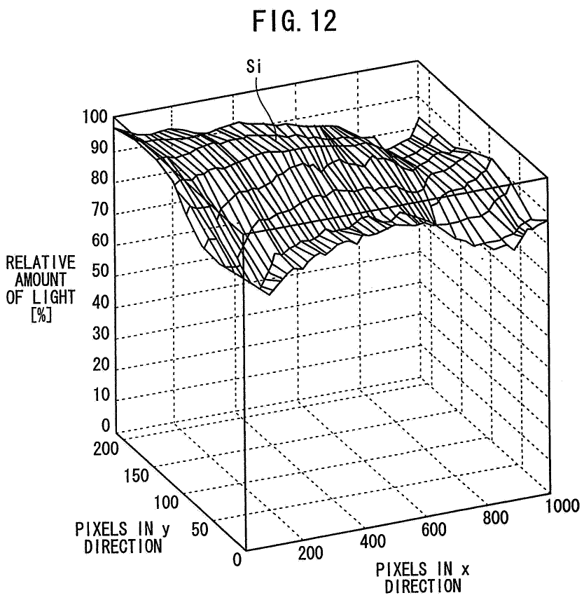

and supplies the calculated amount-of-light locality data Si (i=1, 2, . . . ) to the mask data setting unit 86 (step S3). FIG. 12 shows an example of the amount-of-light locality data Si (i=1, 2, . . . ) calculated by the amount-of-light locality data calculator 88.

The mask data setting unit 86 calculates a minimum value Smin of the supplied amount-of-light locality data Si (i=1, 2, . . . ), and calculates amount-of-light correction data ΔSi (i=1, 2, . . . ) for the respective areas Ki (i=1, 2, . . . ) as follows:

ΔSi=Si−Smin,

(step S4). The mask data setting unit 86 generates mask data for making constant the amounts Pi (i=1, 2, . . . ) of light of the laser beams L from the areas Ki (i=1, 2, . . . ) based on the amount-of-light correction data ΔSi (i=1, 2, . . . ), and stores the mask data in the mask data memory 82 (step S5). The mask data are established as data for controlling particular micromirrors 40 into an off-state such that the relationship:

ΔSi=ni/Ni,

is satisfied where Ni (i=1, 2, . . . ) represents the total number of micromirrors 40 of the areas Ki (i=1, 2, . . . ) and ni (i=1, 2, . . . ) represents the number of micromirrors 40 to be controlled into the off-state. In FIG. 5, those micromirrors 40 that have been set to the off-state by the mask data are illustrated as black dots.

After the mask data have thus been established, a desired wiring pattern is recorded by way of exposure on the substrate F.

First, image data representing a desired wiring pattern are entered from image data input unit 70. The entered image data are stored in the frame memory 72, and then supplied to the resolution converter 74. The resolution converter 74 converts the resolution of the image data into a resolution depending on the resolution of the DMDs 36, and supplies the resolution-converted image data to the output data processor 76. The output data processor 76 calculates output data representing signals for selectively turning on and off the micromirrors 40 of the DMDs 36 from the resolution-converted image data, and supplies the calculated output data to the output data corrector 78.

The output data corrector 78 reads the mask data from the mask data memory 82, corrects the on- and off-states of the micromirrors 40 that are represented by the output data, with the mask data, and supplies the corrected output data to the DMD controller 42.

The DMD controller 42 energizes the DMDs 36 based on the corrected output data to selectively turn on and off the micromirrors 40. The laser beams L output from the light source units 28 and introduced into the exposure heads 24a through 24j are applied via the rod lenses 32 and the reflecting mirrors 34 to the DMDs 36. The laser beams L that are selectively reflected in desired directions by the micromirrors 40 of the DMDs 36 are magnified by the first image focusing optical lenses 44, 46, and then adjusted to a predetermined beam diameter by the microaperture arrays 54, the microlens arrays 48, and the microaperture arrays 56. Thereafter, the laser beams L are adjusted to a predetermined magnification by the second image focusing optical lenses 50, 52, and then guided to the substrate F. The exposure stage 18 moves along the bed 14, during which time a desired wiring pattern is recorded on the substrate F by the exposure heads 24a through 24j that are arrayed in the direction perpendicular to the direction in which the exposure stage 18 moves.

After the desired wiring pattern has been recorded on the substrate F by exposure, the substrate F is removed from the exposure apparatus 10, and then the developing process, the etching process, and the peeling process are performed on the substrate F. The localities of the amounts of light of the laser beams L applied to the substrate F have been adjusted based on the mask data. Therefore, it is possible to obtain a highly accurate wiring pattern having a desired line width.

In the above embodiment, the amounts of light of the laser beams L are detected by the photosensor 68, and the localities thereof are corrected. The beam diameters of the laser beams L may be considered as localities. The beam diameters can be calculated from the period of time in which the laser beams L are applied to the photosensor 68 through a slit formed on the entrance surface of the photosensor 68 and the speed at which the exposure stage 18 with the photosensor 68 fixed thereto moves.

As the beam diameters increase, the line width of the pattern produced as a result of the exposure tends to increase. Therefore, it is preferable to set the number of micromirrors 40 which are to be set to the off-state based on the mask data to a greater value than if the beam diameters are smaller. The localities of the amounts of light of the laser beams L and the localities of the beam diameters may be corrected simultaneously or separately.

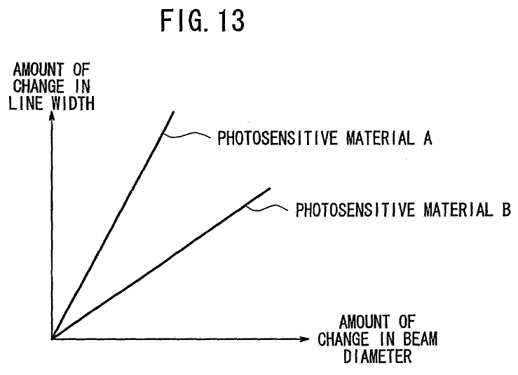

The proportion of changes in the pattern line width to changes in the amounts of light or beam diameters of the laser beams L differs depending on the type of the photosensitive material exposed to light. Therefore, the localities of the amounts of light or the beam diameters should desirably be corrected for each of the types of photosensitive materials. For example, as shown in FIG. 13, the relationship between amounts of change in the beam diameters of the laser beams L applied to the substrate F and amounts of change in the pattern line widths may differ depending on the types of photosensitive materials A, B. The different relationships are caused by different gradation characteristics of the photosensitive materials A, B. It is thus preferable to determine correction variables in view of the different gradation characteristics of the photosensitive materials A, B. The localities of the amounts of light may be corrected based on the amounts of light, and the localities of the beam diameters may be corrected based on the beam diameters and the types of the photosensitive materials. Alternatively, a table representing the relationship between beam diameters and line widths may be prepared, and a locality correction variable may be determined by referring to the table based on the beam diameter.

The localities with respect to the respective areas Ki (i=1, 2, . . . ) may be measured at one time using an area sensor such as a CCD or the like.

The exposure apparatus 10 may appropriately be used to expose a dry film resist (DFR) or a liquid resist in a process of manufacturing a multilayer printed wiring board (PWB), to form a color filter or a black matrix in a process of manufacturing a liquid crystal display (LCD), to expose a DFR in a process of manufacturing a TFT, and to expose a DFR in a process of manufacturing a plasma display panel (PDP), etc., for example. The present invention is also applicable to an image recording apparatus having an ink jet recording head. The present invention is also applicable to exposure apparatus for use in the field of printing and the field of photography.

1. A method of recording an image on an image recording medium by controlling a plurality of recording components depending on image data, comprising the steps of:
dividing the recording components into recording component groups of adjacent recording components, and determining a locality of recording characteristics between said recording component groups;
determining mask data for controlling particular recording components of said recording component groups into an off-state, based on said locality; and
controlling said recording components based on the image data for determining on- and off-states and said mask data for determining the off-state to record the image on said image recording medium.

2. A method according to claim 1, wherein said locality is determined as a locality of each of said recording component groups which are arranged in a two-dimensional array along said image recording medium.

3. A method according to claim 1, wherein correction data for correcting said locality are determined, and said mask data are determined based on said correction data.

4. A method according to claim 1, wherein said recording components make up a spatial light modulator for modulating a light beam depending on said image data and recording the image on said image recording medium by way of exposure to the modulated light beam, and said locality comprises a locality of amounts of light and/or beam diameters of said light beams caused by said recording component groups.

5. A method according to claim 4, wherein said correction data are set with respect to a type of said image recording medium.

6. An apparatus for recording an image on an image recording medium by controlling a plurality of recording components depending on image data, comprising:
locality measuring means for measuring a locality caused by recording component groups of adjacent recording components;
mask data setting means for setting mask data for controlling particular recording components of said recording component groups into an off-state in order to correct said locality caused by said recording component groups;
mask data storage means for storing said mask data; and
recording component control means for controlling said recording components based on the image data for determining on- and off-states and said mask data for determining the off-state.

7. An apparatus according to claim 6, wherein said recording components are provided as recording component groups which are arranged in a two-dimensional array.

8. An apparatus according to claim 6, wherein said recording components make up a spatial light modulator for modulating a light beam depending on said image data and recording the image on said image recording medium by way of exposure to the modulated light beam, and said locality comprises a locality of amounts of light and/or beam diameters of said light beams caused by said recording component groups.

9. An apparatus according to claim 8, wherein said correction data are set with respect to a type of said image recording medium.

10. An apparatus according to claim 8, wherein said spatial light modulator comprises a micromirror device including a two-dimensional array of micromirrors having reflecting surfaces for reflecting said light beam, said reflecting surfaces being angularly variable depending on said image data.
